(19) United States
(12) Patent Application Publication
(10) Pub. No.: US 2012/0206147 A1
(43) Pub. Date: Aug. 16, 2012

(54) ELECTROSTATIC CAPACITIVE SENSOR

(75) Inventors: Dongyonn Sim, Tokyo (JP); Masaru Soeda, Tokyo (JP)

(73) Assignee: AZBIL CORPORATION, Tokyo (JP)

(21) Appl. No.: 13/501,845

(22) PCT Filed: Oct. 12, 2010
(86) PCT No.: PCT/JP2010/067889

§ 371 Date: Apr. 13, 2012

(30) Foreign Application Priority Data
Oct. 16, 2009 (JP) 2009-239263

(51) Int. Cl. G01R 29/12

(52) U.S. Cl. 324/457

(57) ABSTRACT

An electrostatic capacitive sensor able to detect a first electrostatic capacitance and a second electrostatic capacitance, comprising: a member wherein is formed a movable diaphragm that has electrical conductivity; a thin-film electrode that forms a first electrostatic capacitance with the diaphragm; a thin-film electrode that forms a second electrostatic capacitance with the diaphragm; an upper member that is provided so as to form a space between itself and the top face of the diaphragm; and a tower member that is provided so as to form a second space between itself and the bottom face of the diaphragm; wherein: a gas is filled into the space and another gas, which has a coefficient of thermal expansion different from that of the gas, is filled into the second space.

### CROSS REFERENCE TO PRIOR APPLICATIONS

This application is a U.S. National Phase application under 35 U.S.C. §371 of International Application No. PCT/JP2010/067889, filed on Oct. 12, 2010 and claims benefit of priority to Japanese Patent Application No. 2009-239263, filed on Oct. 16, 2009. The International Application was published in Japanese on Apr. 21, 2011 as WO 2011/046119 A1 under PCT Article 21(2). All of these applications are herein incorporated by reference.

### FIELD OF TECHNOLOGY

Several forms relating to the present invention relates to electrostatic capacitive sensors that can detect, for example, temperature.

### BACKGROUND

Conventionally, it has been known that it is possible to increase noise resistance through the provision of a temperature detecting portion that has two mutually differing types of metal materials and a protective tube for protecting the same, as an electric thermometer that uses, for example, a platinum resistor, a thermocouple, a semiconductor temperature sensor, or the like, and forming the two different types of metal materials into a twisted pair or into a coaxial cable (See, for example, Japanese Unexamined Patent Application Publication 118-86694).

In an electric thermometer, the temperature detecting portion is covered with a protective tube or package, or the like, in order to prevent the effects of external noises. Consequently, a somewhat lengthy time, for example, several minutes for several seconds, depending on the type, is required as the time for the temperature detecting portion to arrive at the same temperature as the temperature to be measured (where, in the below, the time until arriving at 63.2% of the temperature to be measured shall be termed the “response time,” and the time until arriving at 90% shall be termed the “stabilization time”). Consequently, this requires response time (or stabilization time) after power is applied, and thus this has been ill-suited to so-called intermittent operation wherein power is applied (the unit is operated) when performing the temperature measurement, and stopped after the temperature measurement.

Conventionally, in order to handle this type of situation, power is applied constantly in an electric thermometer (electric energy is constantly provided to the electric thermometer), making it possible to measure the temperature instantly at the time of a temperature measurement. However, in this method, power is consumed at times other than when measuring temperatures, thus making it difficult to reduce the amount of energy consumed. That is, there is a problem in that is not possible to reduce the amount of electric power consumed, and a problem in that is not possible to form intermittent operation in order to reduce the consumption of electric power.

Several examples of the present invention were created in contemplation of the problem set forth above, and one object is to provide an electrostatic capacitive sensor wherein intermittent operation is possible along with being able to reduce the consumption of electric power.

### SUMMARY

The electrostatic capacitive sensor according to examples of the present invention has an electrostatic capacitive sensor able to detect a first electrostatic capacitance and a second electrostatic capacitance, including a first member wherein is formed a movable electrode plate that has electrical conductivity; a first electrode that forms a first electrostatic capacitance with the electrode plate; a second electrode that forms a second electrostatic capacitance with the electrode plate; a second member that is provided so as to form a first space between itself and one face of the electrode plate; and a third member that is provided so as to form a second space between itself and the other face of the electrode plate; wherein: a first gas is filled into the first space and a second gas, which has a coefficient of thermal expansion different from that of the first gas, is filled into the second space.

Given this structure, a first gas is sealed in a first space and a second gas, having a different coefficient of thermal expansion from the first gas, is sealed in a in a second space. Here, if the first gas and the second gas, having mutually differing coefficients of thermal expansion, are sealed, respectively, into a first space and a second space, then when there is a change in the temperature of, for example, the external atmosphere, the temperatures of the internal first gas and second gas also change. At this time, a pressure difference between the pressure of the first gas and the pressure of the second gas is produced by the difference in the coefficients of thermal expansion between the first gas and second gas. An electrode plate that is disposed between the first space and the second space is dislocated in accordance with the pressure difference, changing a first electrostatic capacitance and a second electrostatic capacitance. Consequently, it is possible to measure the temperature that is to be measured, through detecting the first electrostatic capacitance and the second electrostatic capacitance. Moreover the electrode plate is dislocated in accordance with the change in the temperature to be measured, without the application of electric power, making it possible to detect the first electrostatic capacitance and the second electrostatic capacitance immediate when power is applied. Moreover, because two electrodes that are separated from the other to form an electrostatic capacitance, that is, a capacitor, have an impedance (a capacitive reactance) that is increased through the application of a low-frequency AC voltage, it is possible to reduce the electric current that flows when power is applied.

Moreover, the electrostatic capacitive sensor according to the examples of present invention have an electrostatic capacitive sensor able to detect a first electrostatic capacitance and a second electrostatic capacitance, including a first member wherein is formed a movable electrode plate that has electrical conductivity; a first electrode that forms a first electrostatic capacitance with the electrode plate; a second electrode for forming a second electrostatic capacitance; a second member that is provided so as to form a first space between itself and one face of the electrode plate; and a third member that is provided so as to form a second space between itself and the other face of the electrode plate; wherein: a first gas is filled into the first space and a second gas, which has a coefficient of thermal expansion different from that of the first gas, is filled into the second space.

Preferably, the first member has electrical conductivity, and forms an electrode portion that forms a second electrostatic capacitance with the second electrode.

Preferably, a third electrode for forming a second electrostatic capacitance with the second electrode is also provided.

Preferably, a fourth member, having electrical conductivity, wherein is formed an electrode portion for forming the second electrostatic capacitance with the second electrode, is also provided.

Preferably, the electrode plate has a mesa shape on the face that faces the space into which is filled the gas, of the first gas and the second gas, that has the higher coefficient of thermal expansion.

Preferably, the first member includes a first electrically conductive layer wherein the electrode plate is formed, a second electrically conductive layer, and an insulating layer that is interposed between the first electrically conductive layer and the second electrically conductive layer.

Preferably, the first member includes a first electrically conductive layer wherein the electrode plate is formed, a second electrically conductive layer for forming a second electrode, and an insulating layer that is interposed between the first electrically conductive layer and the second electrically conductive layer.

Preferably, the first member is formed with a third space that contains a gettering material and that is connected to the first space, and the first gas is a vacuum state.

The electrostatic capacitive sensor according to the present examples is able to measure the temperature that is to be measured, through detecting the first electrostatic capacitance and the second electrostatic capacitance. Moreover the electrode plate is dislocated in accordance with the change in the temperature to be measured, without the application of electric power, making it possible to detect the first electrostatic capacitance and the second electrostatic capacitance immediate when power is applied. Moreover, because two electrodes that are separated from the other to form an electrostatic capacitance, that is, a capacitor, have an impedance (a capacitive reactance) that is increased through the application of a low-frequency AC voltage, it is possible to reduce the electric current that flows when power is applied. This makes it possible to measure temperatures without the constant supply of electrical energy, making it possible to reduce the consumption of electric power. Moreover, this makes it possible to compress the response time (and stabilization time) substantially, enabling intermittent operation.

### BRIEF DESCRIPTION OF THE DRAWINGS

FIG. 1 is a side-view cross-sectional diagram of an electrostatic capacitive sensor according to an example of the present invention.

FIG. 2 is a plan view diagram for explaining the state of the diaphragm illustrated in FIG. 1.

FIG. 3 is a diagram for explaining the electrostatic capacitance detected by the electrostatic capacitive sensor illustrated in FIG. 1.

FIG. 4 is a graph for explaining the relationship between temperature and pressure in the gases that are sealed into the closed spaces.

FIG. 5 is a graph for explaining the relationship between the temperature of the gases that are sealed into the closed spaces and the dislocation of the diaphragm.

FIG. 6 is a side-view cross-sectional diagram of an electrostatic capacitive sensor according to another example.

FIG. 7 is a diagram for explaining the electrostatic capacitance detected by the electrostatic capacitive sensor illustrated in FIG. 6.

FIG. 8 is a side-view cross-sectional diagram illustrating another example of an electrostatic capacitive sensor according to the present invention.

FIG. 9 is a side-view cross-sectional diagram illustrating another example of an electrostatic capacitive sensor according to the other example.

FIG. 10 of is a side view cross-sectional diagram illustrating an electrostatic capacitive sensor according to further example.

FIG. 11 is a side-view cross-sectional diagram illustrating another example of an electrostatic capacitive sensor according to the other example.

FIG. 12 is a side-view cross-sectional diagram of an electrostatic capacitive sensor according to a yet further example.

FIG. 13 is a plan view diagram for explaining the state of the diaphragm illustrated in FIG. 12.

FIG. 14 is a side-view cross-sectional diagram illustrating another example of an electrostatic capacitive sensor according to the further example

FIG. 15 is a side-view cross-sectional diagram of an electrostatic capacitive sensor according to an example of the present invention.

FIG. 16 is a top view diagram of the electrode portion illustrated in FIG. 15.

FIG. 17 is a side-view cross-sectional diagram illustrating another example of an electrostatic capacitive sensor according to examples above.

FIG. 18 is a side-view cross-sectional diagram of an electrostatic capacitive sensor according to another example.

FIG. 19 is a side-view cross-sectional diagram illustrating another example of an electrostatic capacitive sensor.

FIG. 20 is a side-view cross-sectional diagram illustrating another example of an electrostatic capacitive sensor according the present invention.

FIG. 21 is a side-view cross-sectional diagram illustrating yet another example of an electrostatic capacitive sensor.

### DETAILED DESCRIPTION

An example of the present invention is described below. In the descriptions of the drawings below, identical or similar components are indicated by identical or similar codes. Note that the diagrams are schematic. Consequently, specific measurements should be evaluated in light of the descriptions below. Furthermore, even within these drawings there may, of course, be portions having differing dimensional relationships and proportions.

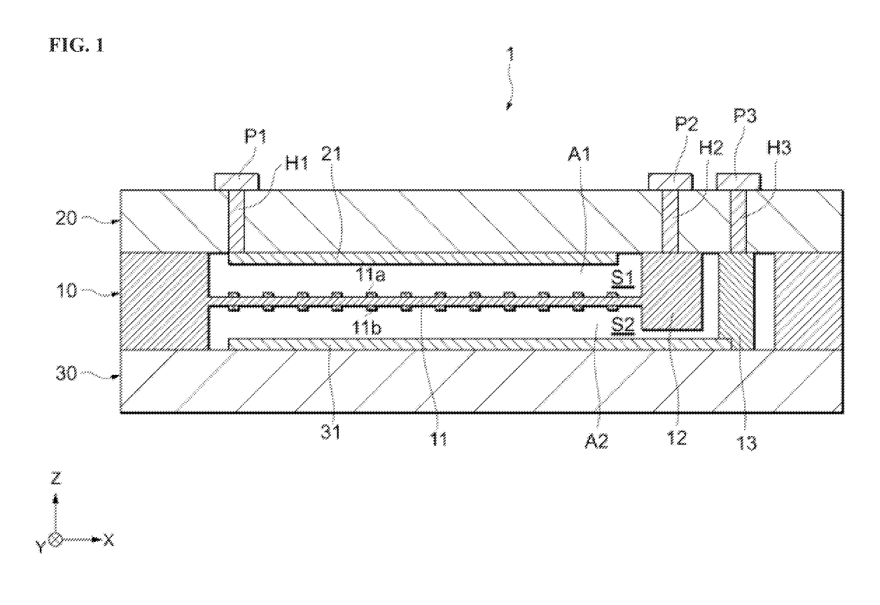

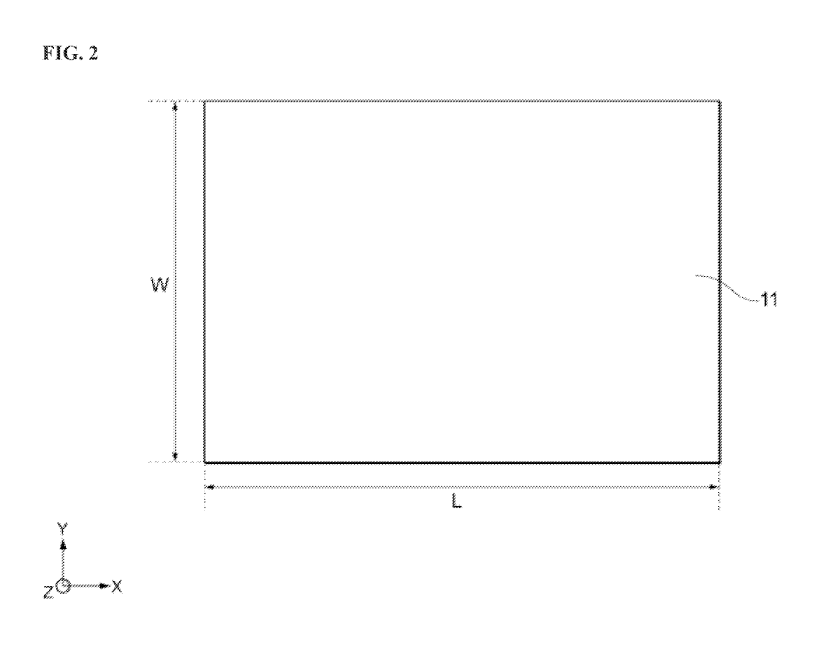

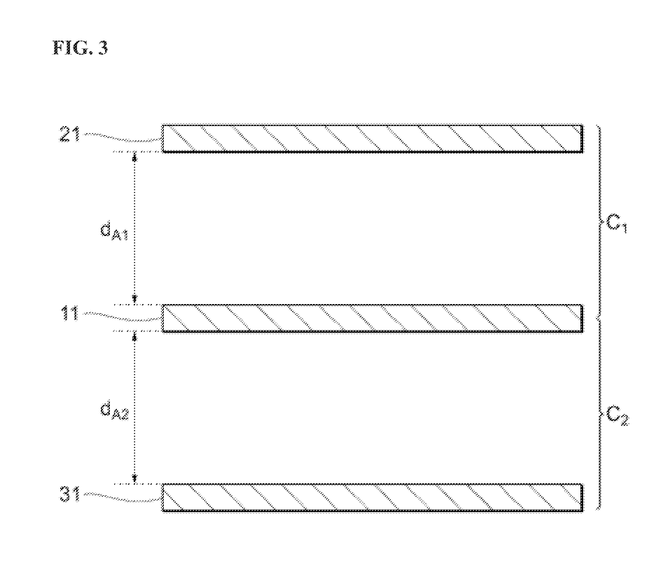

FIG. 1 through FIG. 5 are for explaining an example of an electrostatic capacitive sensor according to the present invention. FIG. 1 is a side-view cross-sectional diagram of an electrostatic capacitive sensor; FIG. 2 is a plan view diagram for explaining the state of the diaphragm illustrated in FIG. 1; and FIG. 3 is a diagram for explaining the electrostatic capacitance detected by the electrostatic capacitive sensor illustrated in FIG. 1. Note that the X axis, Y axis, and Z axis in FIG. 1 and FIG. 2 are mutually perpendicular coordinate axes, where the Y axis is perpendicular to the X axis in the horizontal plane, and the Z axis is perpendicular to the X axis in the vertical direction. Furthermore, this is also true for the subsequent diagrams. Moreover, in the explanations below the top of the figure shall be defined as “up,” the bottom of the figure shall be defined as “down,” the left side of the figure shall be defined as “left,” and the right side of the figure shall be defined as “right.”

As illustrated in FIG. 1, the electrostatic capacitive sensor is for measuring the temperature of something for which the temperature is to be measured, such as the ambient atmosphere, or the like. The electrostatic capacitive sensor 1 is provided with an electrically conductive member 10, an upper member 20 that is provided above the member 10, and a lower member 30 that is provided below the member 10.

The member 10 is structured from, for example, electrically conductive single crystal silicon (low-resistance silicon). A diaphragm 11 able to dislocate in a specific direction (the direction of the Z axis in FIG. 1) is formed in the member 10. As illustrated in FIG. 2, the diaphragm 11 has, in the plan view, a rectangular shape with a length L in the long direction (the direction of the long edge, which is the direction of the X axis in FIG. 2) and a length W in the short direction (the direction of the short edge, which is the direction of the Y axis in FIG. 2). The diaphragm 11 functions as a movable electrode plate that has a thickness (a length in the direction of the Z axis in FIG. 1) that is thinner than that of the member 10.

Note that the shapes of the top face and the bottom face of the diaphragm 11 are not limited to the planer (flat) shapes as illustrated in FIG. 1, but one or more of these faces may be a corrugated (wavy) shape. Moreover, the shape of the diaphragm 11 in the plan view is not limited to being rectangular as illustrated in FIG. 2, but rather may be a square shape, a polygonal shape, a circular shape, an elliptical shape, or the like.

As illustrated in FIG. 1, protrusions 11a and 11b are formed in the shape of thin films, each being electrically insulating, on the top face and the bottom face of the diaphragm 11. Doing so enables the electrical insulation of the thin-film electrodes 21 and 31, described below, and making it possible to prevent sticking.

The upper member 20 is structured from, for example, ceramic. The bottom face of the upper member 20 is bonded to the top face of the member 10 so as to form an airtight space S1 between the bottom face of the upper member 20 and the top face of the diaphragm 11. Moreover, a thin-film electrode 21 is provided at a position facing the diaphragm 11 on the bottom face of the upper member 20. As illustrated in FIG. 3, the thin-film electrode 21 is separated by a gap d_{A1} from the diaphragm 11, to form an electrostatic capacitance C₁ with the diaphragm 11. The thin-film electrode 21 and the diaphragm 11 function as a capacitor.

As illustrated in FIG. 1, the lower member 30 is structured from, for example, ceramic. The top face of the lower member 30 is bonded to the bottom face of the member 10 so as to form an airtight space S2 between the top face of the lower member 30 and the bottom face of the diaphragm 11. Moreover, a thin-film electrode 31 is provided at a position facing the diaphragm 11 on the top face of the lower member 30. As illustrated in FIG. 3, the thin-film electrode 31 is separated by a gap d_{A2} from the diaphragm 11, to form an electrostatic capacitance C₂ with the diaphragm 11. The thin-film electrode 31 and the diaphragm 11 function as a capacitor.

The bonding between the member 10 and the upper member 20 or lower member 30 is performed using mechanical bonding, direct bonding, an anode bonding method, or the like, in consideration of the airtightness of the spaces S1 and S2.

The materials for the upper member 20 and the lower member 30 are not limited to ceramic, but one or more of these may be made from a borate glass (an alkali glass), quartz, crystal, or sapphire, that can be bonded using an aforementioned bonding method. Specifically, in the case of anode bonding Pyrex™ glass, TEMPAX, SD2 glass, SW-Y and SW-YY glass, or LTCC (low-temperature co-fired ceramic), or the like, may be used. Moreover, electrically conductive silicon, similar to that of the member 10, or a metal may instead be used as the material for the upper member 20 and/or the lower member 30. In this case, bonding to the member 10 would be through an insulating layer. Moreover, a crystal or polycrystal that can form an electrostatic capacitance with the diaphragm 11 and that has an electrically conductive thin-film electrode may be used as the material for the upper member 20 and/or the lower member 30.

As illustrated in FIG. 1, the left end portion of the thin-film electrode 21 is connected to an electrically conductive field through-hole electrode H1. The field through-hole electrode H1 is connected electrically to an electrode pad (terminal) P1 that is disposed on the top face of the upper member 20. The right end of the diaphragm 11 is connected to an electrically conductive portion 12 that structures a portion of the member 10. The electrically conductive portion 12 is connected through an electrically conductive through-hole electrode H2 to a diaphragm pad (terminal) P2 that is disposed on the top face of the upper member 20. The right end portion of the thin-film electrodes 31 is connected to a silicon island 13 that forms a portion of the member 10. The silicon island 13 is connected electrically to an electrode pad (terminal) P3 that is disposed on the top face of the upper member 20, through the electrically conductive field through-hole electrode 113.

The electrostatic capacitance C₁ can be detected through applying an AC voltage at a specific frequency to the electrode pad P1 and the diaphragm pad P2, for example, and measuring the electric current that flows at the time of said application. Moreover, the electrostatic capacitance C₂ can be detected through applying an AC voltage at a specific frequency to the electrode pad P4 and the diaphragm pad P2, for example, and measuring the electric current that flows at the time of said application.

The formation of the individual field through-hole electrodes H1 through H3 is performed through forming the individual through-holes (not shown) in the upper member 20, and then performing filling film deposition, plating, filling wiring, or the like, for the electrode material into the through-holes.

The fabrication of the electrically conductive portion 12 and the silicon island 13 is performed through, for example, a gas-phase chemically reactive etching method, such as dry etching, or a water-soluble chemical etching method, or the like. Moreover, the fabrication of the diaphragm 11 is performed through controlling the thickness, through the etching time, using a water-soluble chemical etching method, or through diffusion of a high concentration of impurities into a position on the member 10 corresponding to the diaphragm.

A gas A1, for example, a gas in a vacuum state, is sealed into the space S1, and a gas A2, for example, an inert gas that has a coefficient of thermal expansion that is different from that of the gas that is sealed into the space Si is sealed into the space S2.

In the present example, the “vacuum state” does not imply a state wherein there is nothing, but rather refers to a state wherein the pressure is lower than that of atmospheric pressure (that is, a negative pressure). Consequently, because there is a substance (which, in the present application, is a gas) even when the space is in the vacuum state, the gas that exists in this space is expressed as being a “gas in a vacuum state.”

Note that the combination of the gas that is sealed in the space Si and the gas that is sealed in the space S2 is not limited to that which is described above, but need only have mutually differing coefficients of thermal expansion, or, more precisely, differing bulk moduli. For example, the gas A1 may be a first inert gas and the gas A2 may be a second inert gas or dry air. However, a gas with high humidity would produce condensation when the temperature drops, which would have a large effect on the volumetric change of the gas, described below. Thus preferably the gas is one wherein condensation is unlikely, such as a gas in a vacuum state, an inert gas, dry air, or the like.

Here, when the gas A1 and the gas A2, which have mutually differing coefficients of thermal expansion, are sealed respectively into the closed spaces S1 and S2, then when there is a change in the temperature of the external atmosphere, for example, there is a change in pressure also in the internal gases A1 and A2. At this time, a pressure difference is produced between the pressure in the space S1 and the pressure in the space S2 due to the difference in coefficients of thermal expansion between the gas A1 and the gas A2. The diaphragm 11 that is disposed between the space S1 and the space S2 dislocates in accordance with the pressure difference, producing a change in the electrostatic capacitance C₁ and the electrostatic capacitance C₂. Consequently, it is possible to measure, through detecting the electrostatic capacitance C₁ and the electrostatic capacitance C₂, the temperature of that which is to be measured. Moreover, the diaphragm 11 dislocates in accordance with the change in the temperature of that which is to be measured, without the application of an electric current, thus making it possible to detect the electrostatic capacitance C₁ and the electrostatic capacitance C₂ immediately upon the application of the electric current. Moreover, because two electrodes that are separated from the other to form an electrostatic capacitance, that is, a capacitor, have an impedance (a capacitive reactance) that is increased through the application of a low-frequency AC voltage, it is possible to reduce the electric current that flows when power is applied.

Conventionally, glass thermometers and liquid-filled thermometers, along with metal thermometers and bimetallic thermometers, are known as thermometers that can reduce the consumption of electric power. Glass thermometers and liquid-filled thermometers use the property of thermal expansion of a substance due to the change in temperature of that which is being measured, making it possible to measure the temperature without requiring electrical energy like it is in an electric thermometer. However, the temperature that is measured is, fundamentally, read out visually from a graduated scale, making conversion into an electrical signal and making accurate temperature measurements difficult. Moreover, while it is possible to convert, into an electric signal, the temperature of the graduated scale through the addition of an image sensor and signal processing circuitry, doing so would engender the risk of increasing costs and electric power consumption. On the other hand, the measured temperature can be converted easily into an electric signal in a metal thermometer or bimetallic thermometer. However, in order to maintain the sensitivity to temperature, the structure is one wherein the detecting portion is exposed, making it susceptible to external noises such as humidity, vibration, dirt, dust, and the like.

In contrast, the electrostatic capacitive sensor 1 according to the present example is able to convert the temperature into an electric signal easily through detecting the electrostatic capacitance C₁ and the electrostatic capacitance C₂. Moreover, because the gas A1 and the gas A2 are sealed respectively into the closed space S1 and space S2, there is the benefit of not being susceptible to the effects of external noises.

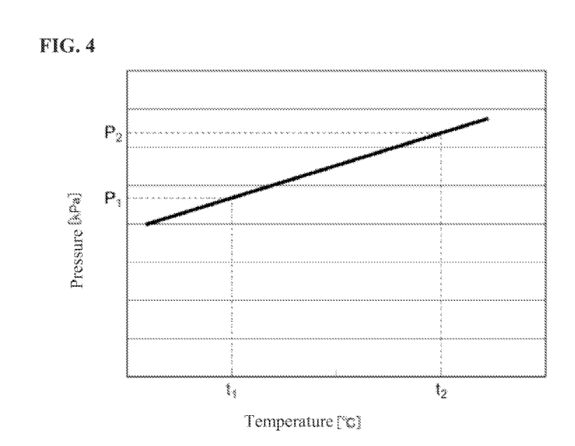

The relationships between temperature changes in that which is to be measured and the changes in electrostatic capacitance of the electrostatic capacitive sensor is explained next in detail using FIG. 4 through FIG. 6. Note that unless otherwise specified, in the below the gas A1 is a gas in a vacuum state and the gas A2 is an inert gas.

FIG. 4 is a graph for explaining the relationship between temperature and pressure in the gases that are sealed into the closed spaces. Typically, when a gas is sealed into a closed space having a specific volume, the behavior (action) of that gas can be expressed approximately using the equation of state for an ideal gas. That is, assuming a volume v₀ and pressure p₀ at absolute zero (absolute temperature), then at a specific temperature t₁, the pressure p₁ and the volume v₁ will satisfy the relationships in Equation (1) and Equation (2), below:

p₁v₁=p₀v₀(1+βt₁) (1)

v₁=v₀(1+gt₁) (2)

Note that here β is the bulk modulus of the gas and g is the bulk modulus of the sealing material in which the space is enclosed.

Similarly, at another specific temperature t₂, the pressure p₂ and the volume v₂ will satisfy the relationships in Equation (3) and Equation (4), below:

p₂v₂=p₀v₀(1+βt₂) (3)

v₂=v₀(1+gt₂) (4)

Here, when there is a change in temperature from t₁ to t₂ in the gas that is sealed in the closed space, then the pressure p₂ after the change in temperature can be expressed by Equation (5), below, through simplifying and combining Equation (1) through Equation (4):

p₂={(1+βt₂)/(1+βt₁)}{(1+gt₁)/(1+gt₂)}×p₁ (5)

It can be seen that when the pressure p₂ is calculated using Equation (5), the relationship between the temperature and the pressure in the gas that is sealed in the closed space is a linear relationship, as shown in FIG. 4.

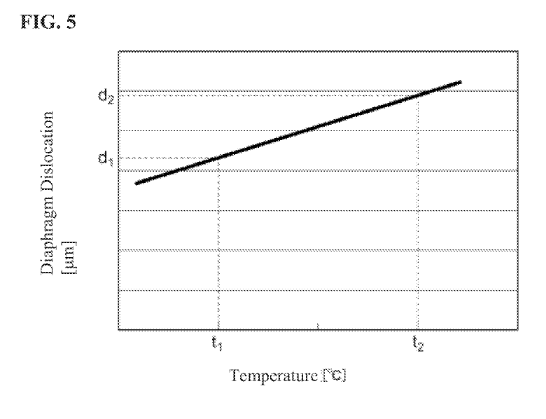

FIG. 5 is a graph for explaining the relationship between the temperature of the gases that are sealed into the closed spaces and the dislocation of the diaphragm. FIG. 5 is a graph for explaining the relationship between the temperature of the gas that is sealed in a closed space and the dislocation of the diaphragm. According to one paper (Stephen P. Timoshenko, S. Woinowsky-Krieger, “Theory of Plates and Shells,” New York: McGRAW-HILL, Inc., 2nd Edition.), typically, in the case of a diaphragm with fixed edges that has a rectangular shape when viewed from above, the dislocation w(x,y) in the vertical direction (for example, the direction of the Z axis in FIG. 2) at a coordinate (x,y) in the plane can be expressed by Equation (6) and Equation (7) using the pressure p that is applied to the diaphragm.

$$\begin{matrix} Expression 1 & \\ w ( x , y ) = {{[ I - {( \frac{2 x}{a} )}^{2} ]}^{2} [ I - {( \frac{2 y}{b} )}^{2} ]}^{2} \times \{ {A}_{m} \frac{p {a}^{4}}{16 D} + {B}_{m} \frac{{pa}^{4}}{16 D} [ {( \frac{2 x}{a} )}^{2} + {( \frac{2 y}{b} )}^{2} ] + {C}_{m} \frac{{pa}^{4}}{16 D} {( \frac{2 x}{a} )}^{2} {( \frac{2 y}{b} )}^{2} \} & ( 6 ) \\ D = \frac{{Eh}^{3}}{12 ( 1 - {v}^{2} )} & ( 7 )\end{matrix}$$

Here a is the length of the short edge of the diaphragm, b is the length of the long edge of the diaphragm, D is a factor indicating the elastic properties of the diaphragm (the flexural rigidity), Am, Bm, and Cm are shape constants, E is the Young's modulus of the material of the diaphragm, h is the thickness of the diaphragm, and v is the Poisson's ratio of the diaphragm material.

Note that it is still possible to express the dislocation w(x,y) similarly using the pressure p that is applied to the diaphragm, through a modification of Equation (6), even if the shape of the diaphragm, when viewed from above, is other than a rectangle.

Here let us consider the application of this theory, described above, to the present invention. That is, assuming a maximum dislocation d1 of the diaphragm 11 at a temperature t1, and a change from t1 to t2 in the temperature of the gas that is sealed into the closed space, there is no change (or essentially no change) in the pressure in the space S1 because the gas A1 is a gas in a vacuum state. Consequently, the pressure that is applied to the diaphragm 11 is only the pressure of the space S2. At this time, the maximum dislocation d₂ of the diaphragm 11 can be calculated by substituting p₂ of Equation (5) into the pressure p in Equation (6). As illustrated in FIG. 5, it can be seen that the relationship between the temperature of the gas A2 and the dislocation of the diaphragm 11 is a linear relationship.

Note that while there is a change in pressure in the gas A1 that is sealed in the space S1 due to the change in the temperature, in the case of, for example, an inert gas, still, in the same manner as described above, Equations (1)′ through Equation (4)′ will be satisfied for this space S1 as well, so Equation (5)′ can be derived from these equations. Thus it is possible to calculate, in the same way, the maximum dislocation d2 of the diaphragm 11 through calculating Equation (5)-(5)′(=Δp), and substituting this calculated Δp into the pressure p in Equation (6).

The electrostatic capacitance C in the case of a movable dislocation when the electrodes movably dislocate in the vertical direction can be expressed as Equation (8), below, using the dislocation w(x,y) of the diaphragm 11:

$$\begin{matrix}Expression 2 & \\ C = {\int }_{0}^{a} {\int }_{0}^{b} \frac{{ɛ}_{0}}{d - w ( x , y )} d x d y + {C}_{0} & ( 8 )\end{matrix}$$

Note that C₀ is the electrostatic capacitance at a specific temperature (the initial temperature), ε₀ is the dielectric constant in a vacuum, and d is the distance between the electrodes in the initial state.

Additionally, the change in the electrostatic capacitance ΔC of the electrostatic capacitive sensor 1 can be defined using Equation (9), below:

ΔC=(C₁-C₂)/C₂ (9)

Consequently, it is possible to express the change in the electrostatic capacitance ΔC of the electrostatic capacitive sensor 1 in terms of temperature (that is, as a function of temperature) through calculating Equation (9) by substituting Equation (6) into the dislocation w(x,y) in Equation (8). The change in electrostatic capacitance ΔC can be given linearity with respect to temperature through a correcting method, even if there is variability in the sensor or in the manufacturing process that causes non-linear characteristics with respect to the change in temperature.

While in the present example an electrical conductor was used as the material for the member 10, there is no limitation thereto. For example, an insulating material may be used, and a thin film of an electrically conductive substance may be formed on the top face and bottom face (both faces) of the diaphragm 11. In this case, the electrically conductive portion 12 and the silicon island 13 are formed from an electrically conductive substance in the same way.

In this way, the electrostatic capacitive sensor 1 according to the present example has a gas A1 sealed in a space S1, and a gas A2, having a different coefficient of thermal expansion from the gas A1, sealed in a space S2. Here, when the gas A1 and the gas A2, which have mutually differing coefficients of thermal expansion, are sealed respectively into the closed spaces S1 and S2, then when there is a change in the temperature of the external atmosphere, for example, there is a change in pressure also in the internal gases A1 and A2. At this time, a pressure difference is produced between the pressure in the space S1 and the pressure in the space S2 due to the difference in coefficients of thermal expansion between the gas A1 and the gas A2. The diaphragm 11 that is disposed between the space S1 and the space S2 dislocates in accordance with the pressure difference, producing a change in the electrostatic capacitance C₁ and the electrostatic capacitance C₂. Consequently, it is possible to measure, through detecting the electrostatic capacitance C₁ and the electrostatic capacitance C₂, the temperature of that which is to be measured. Moreover, the diaphragm 11 dislocates in accordance with the change in the temperature of that which is to be measured, without the application of an electric current, thus making it possible to detect the electrostatic capacitance C₁ and the electrostatic capacitance C₂ immediately upon the application of the electric current. Moreover, because two electrodes that are separated from the other to form an electrostatic capacitance, that is, a capacitor, have an impedance (a capacitive reactance) that is increased through the application of a low-frequency AC voltage, it is possible to reduce the electric current that flows when power is applied. This makes it possible to measure temperatures without the constant supply of electrical energy, making it possible to reduce the consumption of electric power. Moreover, this makes it possible to compress the response time (and stabilization time) substantially, enabling intermittent operation.

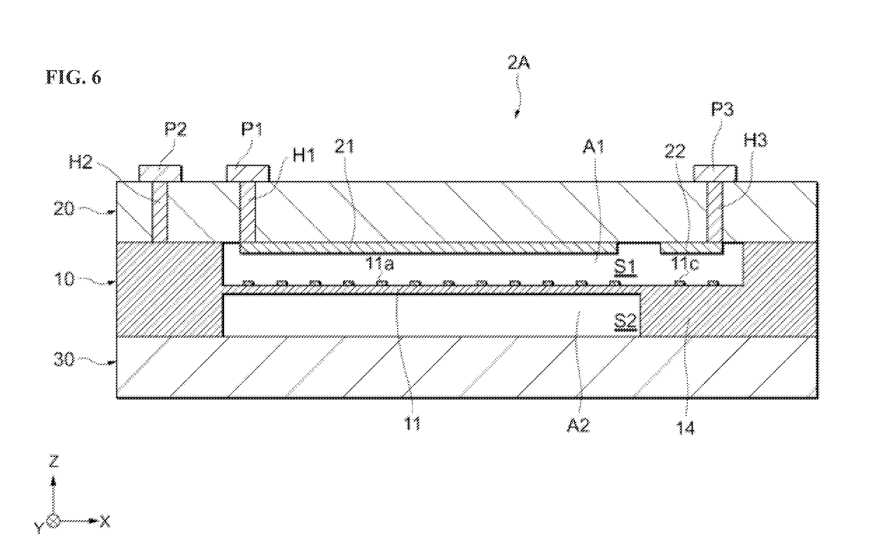

FIG. 6 through FIG. 9 are for explaining another example of an electrostatic capacitive sensor. Note that unless stated otherwise, identical structural parts as those in the above example are indicated by identical codes, and explanations thereof are omitted. Moreover, the structural elements not shown are identical to those in the example set forth above.

The points of difference between the examples are that the electrostatic capacitive sensors 2A, 2B, and 2C are provided with a reference electrode 22, rather than the thin-film electrode 31.

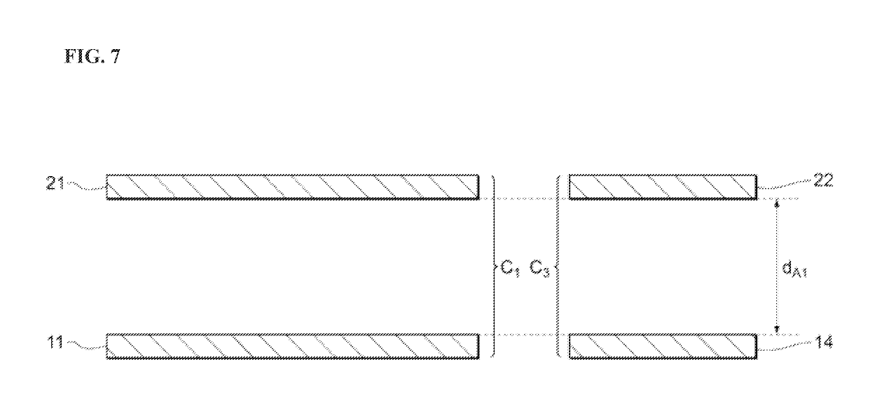

FIG. 6 is a side-view cross-sectional diagram of an electrostatic capacitive sensor according to the other example of the present invention; and FIG. 7 is a diagram for explaining the electrostatic capacitance detected by the electrostatic capacitive sensor illustrated in FIG. 6. As illustrated in FIG. 6, a stationary portion 14 is formed instead of the electrically conductive portion 12 at the right end of the diaphragm 11 in the member 10. In contrast to the diaphragm 11 being able to dislocate in a specific direction (the direction of the Z axis in FIG. 6), the stationary portion 14 is unable to dislocate in at least an applicable specific direction (the direction of the Z axis in FIG. 6) (that is, it is stationary).

A protrusion 11c that is shaped as a thin-film and that is electrically insulating is formed on the top face of the stationary portion 14. Doing so makes it possible to electrically insulate the reference electrode 22, described below, and to prevent sticking.

In addition to the thin-film electrode 21, a reference electrode 22 is provided in the shape of a thin-film, located facing the stationary portion 14, on the bottom face of the upper member 20. As illustrated in FIG. 7, the reference electrode 22 is separated from the stationary portion 14 by a gap d_{A1}, to form an electrostatic capacitance C₃ with the stationary portion 14.The reference electrode 22 and the stationary portion 14 function as a capacitor.

As illustrated in FIG. 6, the left end of the diaphragm 11 is connected to a part (not shown) that forms one portion of the member 10. This part is connected electrically to a diaphragm pad (terminal) P2 through a field through-hole electrode H2. The right end portion of the reference electrode 22 is connected to the field through-hole electrode H3. The field through-hole electrode H3 is connected electrically to the thin-film electrode pad (terminal) P3.

Additionally, the change in the electrostatic capacitance AC of the electrostatic capacitive sensor 2A can be defined using Equation (9)′, below:

ΔC=(C₁-C3)/C3 (9)′

Here, as with the above example, when a pressure difference is produced between the pressure in the space S1 and the pressure in the space S2, then, in contrast to the diaphragm 11 dislocating in accordance with the pressure difference, the stationary portion 14 does not dislocate even when this pressure difference is produced. Consequently, even though there is a change in the electrostatic capacitance C₁ in accordance with the change in temperature, there is no change in the electrostatic capacitance C₃, so that the change in electrostatic capacitance AC of the electrostatic capacitive sensor 2A will be the amount of change in the electrostatic capacitance C₁ due to Equation (9)′.

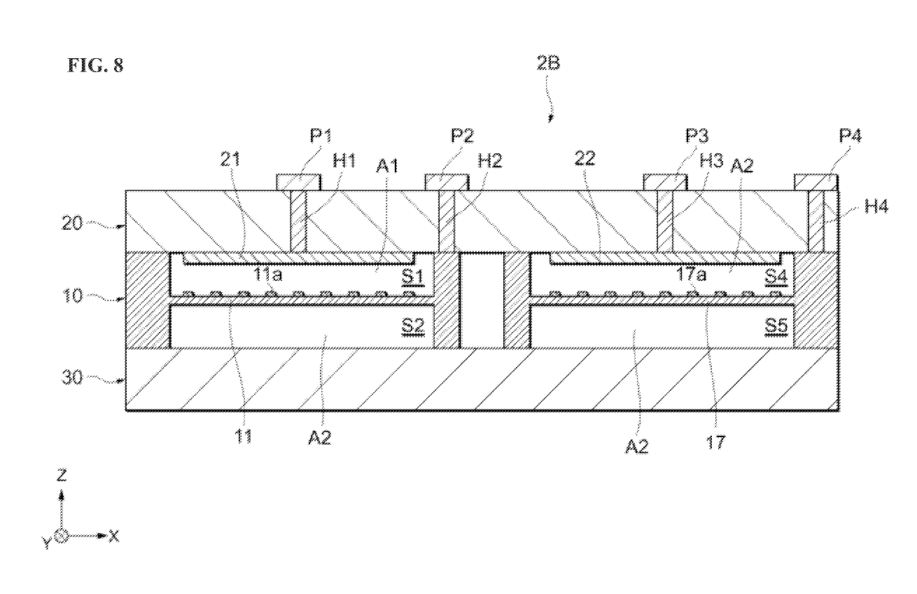

FIG. 8 is a side-view cross-sectional diagram illustrating another example of an electrostatic capacitive sensor according to the above example. While, in this example, a stationary portion 14 is formed at the right end of the diaphragm 11 and an electrostatic capacitance C₃ is formed with this stationary portion 14, there is no limitation thereto. For example, as illustrated in FIG. 8, the electrostatic capacitive sensor 2b may have another diaphragm 17, which is electrically insulated from the diaphragm 11, formed in the member 10. In this case, a protrusion 17a is formed on the top face of the diaphragm 17 in the shape of a thin-film that is electrically insulating. Moreover, a reference electrode 22 is provided at a position facing the top face of the diaphragm 17 on the bottom face of the upper member 20. The reference electrode 22 forms an electrostatic capacitance C₃ with the top face of the diaphragm 17. The reference electrode 22 and the top face of the diaphragm 17 function as a capacitor. The right end of the diaphragm 17 is connected to a part (not shown) that structures a portion of the member 10. This part is connected electrically to a diaphragm pad (terminal) P4 through a field through-hole electrode H4. The reference electrode 22 is connected to the field through-hole electrode H3. The field through-hole electrode H3 is connected electrically to the thin-film electrode pad (terminal) P3.

The gas A2, for example, is sealed in the closed space S4 that is formed between the bottom face of the upper member 20 and the top face of the diaphragm 17. The same gas as in the space S4, for example, the gas A2, is sealed into a closed space S5 that is formed between the top face of the lower member 20 and the bottom face of the diaphragm 17.

Here, when there is a change in the temperature of the external environment, for example, a gas that has an identical coefficient of thermal expansion is filled into the space S4 and the space S5, and thus no pressure difference is produced between the pressure in the space S4 and the pressure in the space S5. Consequently, even though there is a change in the electrostatic capacitance C₁ in response to a change in temperature, in the same way as illustrated in FIG. 6, there is no change in the electrostatic capacitance C₃, and thus the change in the electrostatic capacitance AC of the electrostatic capacitive sensor 2B is an amount of change equal to the electrostatic capacitance C₁ through Equation (9)′.

Note that the electrode for forming the electrostatic capacitance C₃ with the reference electrode 22 is not limited to the diaphragm 17, but rather may also be a stationary electrode (an electrode portion) formed on the member 10, or formed on a member (material) other than the member 10. Moreover, the gas that is filled into the space S4 or the space S5, although preferably the gas A2 from the point that it is an inert gas, is not limited thereto, but may instead be the gas A1 or a different gas.

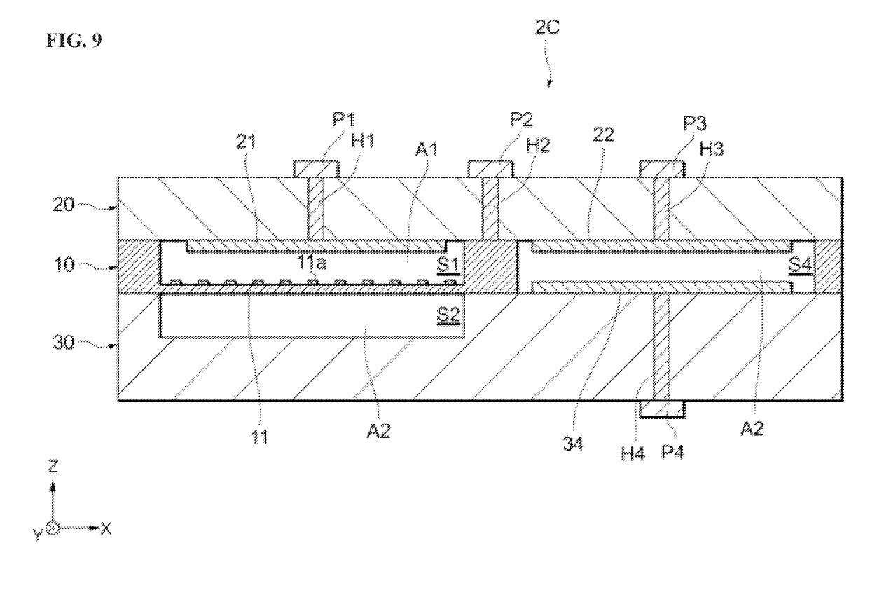

FIG. 9 is a side-view cross-sectional diagram illustrating a further example of an electrostatic capacitive sensor. Moreover, as illustrated in FIG. 9, the electrostatic capacitive sensor 2C may be provided with a reference electrode 22 that is disposed on the bottom face of the upper member 20, and a reference electrode 34, shaped as a thin-film, that is disposed at a position facing the reference electrode 22, on the top face of the lower member 30. The reference electrode 34 may form an electrostatic capacitance C₃ with the reference electrode 22. The reference electrode 22 and the reference electrode 34 function as a capacitor. The reference electrode 34 is connected to the field through-hole electrode H4. The field through-hole electrode H4 is connected electrically to the diaphragm pad (terminal) P4. The reference electrode 22 is connected to the field through-hole electrode H3. The field through-hole electrode H3 is connected electrically to the thin-film electrode pad (terminal) P3.

The gas A2, for example, is sealed in the closed space S4 that is formed between the bottom face of the upper member 20 and the top face of the lower member 30.

Here, when there is a change in the temperature of the external atmosphere, for example, the reference electrode 22 and the reference electrode 34 are stationary, and thus even though the electrostatic capacitance C₁ changes in accordance with the change in temperature in the same manner as in the case illustrated in FIG. 6, there will be no change in the electrostatic capacitance C₃. Thus the change in electrostatic capacitance AC of the electrostatic capacitive sensor 2C will be the amount of change in the electrostatic capacitance C1 through Equation (9)′.

Note that while, in the same manner as in the case illustrated in FIG. 8, preferably the gas that is filled into the space S4 is the gas A2, from the perspective that it is an inert gas, it may instead be the gas A1, or a different gas.

In this way, the electrostatic capacitive sensors 2A, 2B, and 2C in the present example are provided with a reference electrode 22 for forming an electrostatic capacitance C₃. Here, as with the first form of embodiment, when a pressure difference is produced between the pressure in the space S1 and the pressure in the space S2, then, in contrast to the diaphragm 11 dislocating in accordance with the pressure difference, the stationary portion 14, for example, does not dislocate even when this pressure difference is produced. Consequently, even though there will be a change in the electrostatic capacitance C₁ in accordance with the change in temperature, there will be no change in the electrostatic capacitance C₃, so that the change in electrostatic capacitance AC of the electrostatic capacitive sensors 2A, 2B, and 2C will be the amount of change in the electrostatic capacitance C₁ due to Equation (9)′. As a result, it is possible to reduce the consumption of electric power, and also possible to perform intermittent operations, using the structures in the electrostatic capacitive sensors 2A, 2B, and 2C in the same manner as in the above examples.

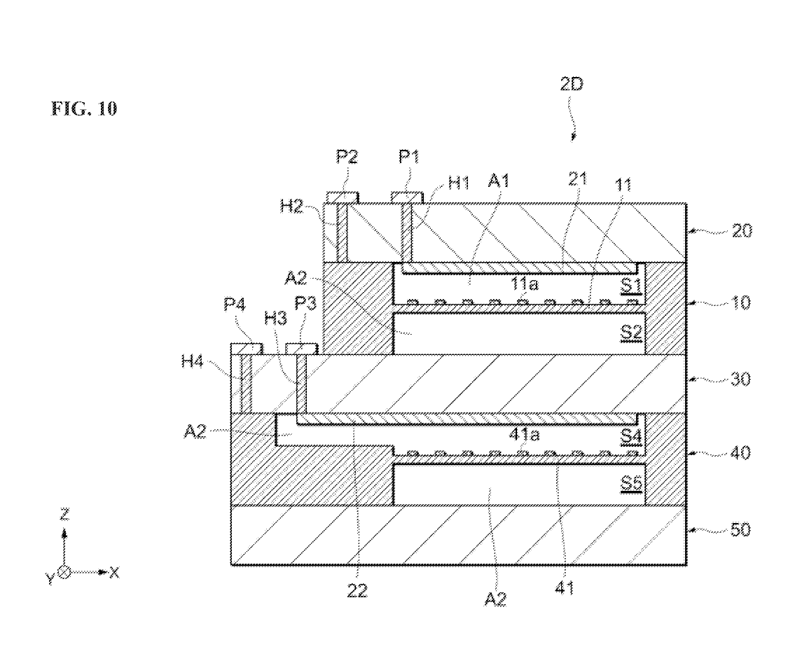

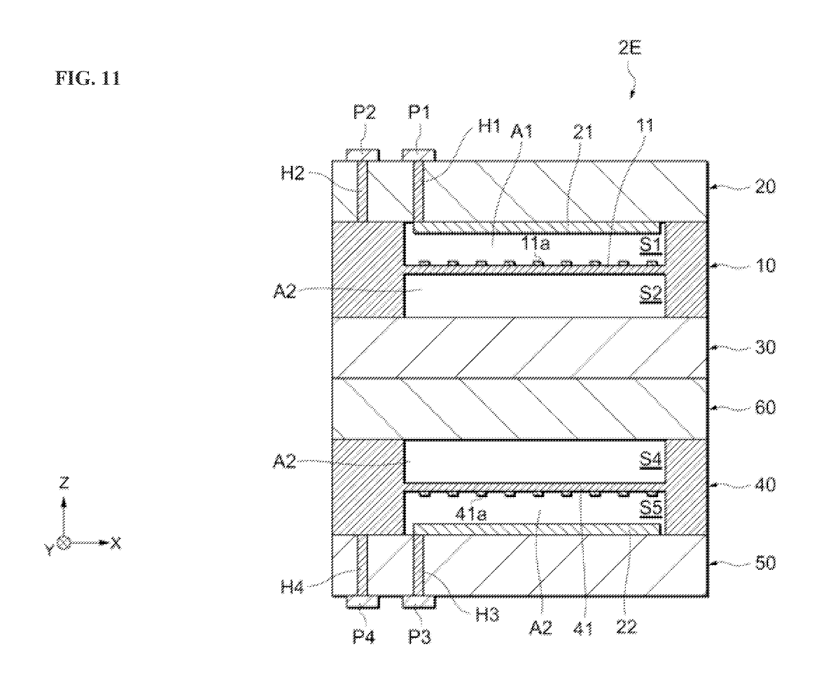

FIG. 10 and FIG. 11 are for explaining alternate examples of the above examples of the electrostatic capacitive sensor. Note that unless stated otherwise, identical structural parts as those above are indicated by identical codes, and explanations thereof are omitted. Moreover, the structural elements not shown are identical to those in the examples set forth above.

The points of difference between the alternate examples are in the further provision of a new member in the electrostatic capacitive sensors 2D and 2E.

FIG. 10 is a side-view cross-sectional diagram of an electrostatic capacitive sensor according to an alternate example. As illustrated in FIG. 10, the electrostatic capacitive sensor 2D is provided with a second member 40 that is provided below the lower member 30, and a second lower member 50 that is provided below the second member 40. The second member 40 is structured from, for example, electrically conductive single crystal silicon (low-resistance silicon). Moreover, the second lower member 50 is structured from ceramic.

A diaphragm 41 is formed in the second member 40. A protrusion 41a of a thin-film shape that is electrically insulating is formed on the top face of the diaphragm 41. A reference electrode 22 is provided on the bottom face of the lower member 30 in a position facing the top face of the diaphragm 41, to form an electrostatic capacitance C3 with the top face of the diaphragm 41. The reference electrode 22 and the top face of the diaphragm 41 function as a capacitor. The left end of the diaphragm 41 is connected to a part (not shown) that structures a portion of the second member 40. This part is connected electrically to a diaphragm pad (terminal) P4 through a field through-hole electrode 114. The left end of the reference electrode 22 is connected to the field through-hole electrode H3. The field through-hole electrode H3 is connected electrically to the thin-film electrode pad (terminal) P3.

The gas A2, for example, is sealed in the closed space S4 that is formed between the bottom face of the lower member 30 and the top face of the diaphragm 41. The same gas as in the space S4, for example, the gas A2, is sealed into a closed space S5 that is formed between the top face of the second lower member 50 and the bottom face of the diaphragm 41.

Here, when there is a change in the temperature of the external environment, for example, a gas that has an identical coefficient of thermal expansion is filled into the space S4 and the space S5, and thus no pressure difference is produced between the pressure in the space S4 and the pressure in the space S5. Consequently, even though there is a change in the electrostatic capacitance C₁ in response to a change in temperature, in the same way as above, there is no change in the electrostatic capacitance C₃, and thus the change in the electrostatic capacitance AC of the electrostatic capacitive sensor 2D will be an amount of change equal to the electrostatic capacitance C₁ through Equation (9)′.

Note that, as with the case illustrated in FIG. 8, the electrode for forming the electrostatic capacitance C₃ with the reference electrode 22 is not limited to the diaphragm 41, but rather may also be a stationary electrode (an electrode portion) formed on the second member 40. Moreover, the gas that is filled into the space S4 or the space S5, although preferably the gas A2 from the point that it is an inert gas, is not limited thereto, but may instead be the gas Al or a different gas.

FIG. 11 is a side-view cross-sectional diagram illustrating another example of an electrostatic capacitive sensor according to an alternate example of the second form of embodiment according to the present invention. In this alternate example, a second member 40 and a second lower member 50 are provided, but there is no limitation thereto. For example, an electrostatic capacitive sensor 2E may be provided further with a second upper member 60 that is provided above the second member 40, as illustrated in FIG. 11. That is, the electrostatic capacitive sensor 2E may be provided with a first electrostatic capacitive sensor (not shown) that includes the member 10, the upper member 20, and the lower member 30, and a second electrostatic capacitive sensor (not shown) that includes the second member 40, the second upper member 60, and the second lower member 50, to be structured from two sensors having essentially identical configurations (structures).

In this case, a protrusion 41a is formed on the bottom face of the diaphragm 41, and a reference electrode 22 is provided on the top face of the second lower member 50, facing the bottom face of the diaphragm 41. The reference electrode 22 forms an electrostatic capacitance C₃ with the bottom face of the diaphragm 41. The reference electrode 22 and the bottom face of the diaphragm 41 function as a capacitor. The left end of the diaphragm 41 is connected to a part (not shown) that structures a portion of the second member 40. This part is connected electrically to a diaphragm pad (terminal) P4 through a field through-hole electrode H4. The left end of the reference electrode 22 is connected to the field through-hole electrode H3. The field through-hole electrode H3 is connected electrically to the thin-film electrode pad (terminal) P3.

The gas A2, for example, is sealed in the closed space S4 that is formed between the bottom face of the second upper member 60 and the top face of the diaphragm 41. The same gas as in the space S4, for example, the gas A2, is sealed into a closed space S5 that is formed between the top face of the second lower member 50 and the bottom face of the diaphragm 41.

Here, when there is a change in the temperature of the external environment, for example, a gas that has an identical coefficient of thermal expansion is filled into the space S4 and the space S5, and thus no pressure difference is produced between the pressure in the space S4 and the pressure in the space S5. Consequently, even though there is a change in the electrostatic capacitance C₁ in response to a change in temperature, in the same way as illustrated in FIG. 10, there is no change in the electrostatic capacitance C₃, and thus the change in the electrostatic capacitance AC of the electrostatic capacitive sensor 2B will be an amount of change equal to the electrostatic capacitance C₁ through Equation (9)′.

Note that, as with the case illustrated in FIG. 10, the electrode for forming the electrostatic capacitance C₃ with the reference electrode 22 is not limited to the diaphragm 41, but rather may also be a stationary electrode (an electrode portion) formed on the second member 40. Moreover, the gas that is filled into the space S4 or the space S5, although preferably the gas A2 from the point that it is an inert gas, is not limited thereto, but may instead be the gas A1 or a different gas.

In this way, it is possible to reduce the consumption of electric power, and also possible to perform intermittent operations, using the structures in the electrostatic capacitive sensors 2D and 2E in the same manner as in the above examples.

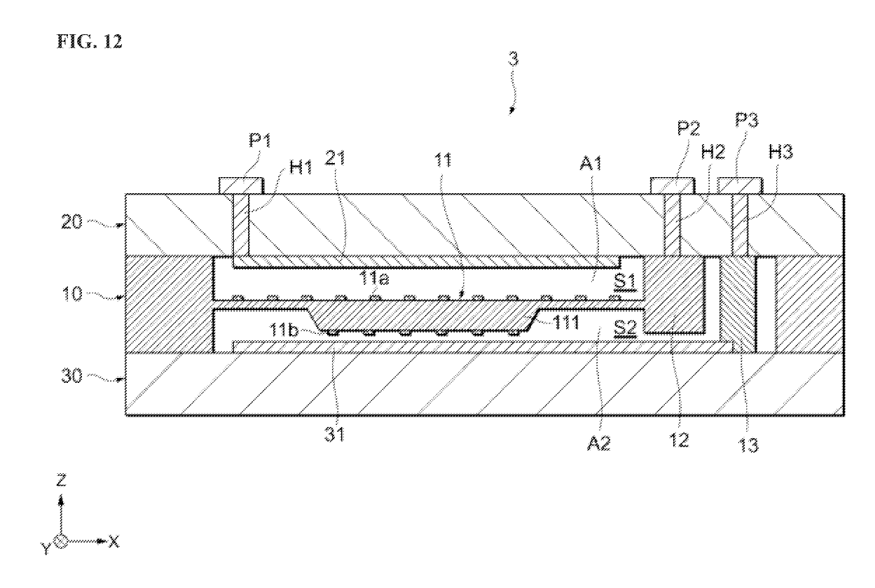

FIG. 12 through FIG. 14 are for explaining a yet further example of an electrostatic capacitive sensor. Note that unless stated otherwise, identical structural parts as those in the above examples are indicated by identical codes, and explanations thereof will be omitted. Moreover, the structural elements not shown are identical to those in the examples set forth above.

The point of difference between the third form of embodiment in the first and second forms of embodiment is in the diaphragm 11 of the electrostatic capacitive sensor 3 having a mesa shape 111.

In the present application, a “mesa shape” refers to a trapezoidal shape, where pairs of opposite edges are parallel or essentially parallel.

FIG. 12 is a side-view cross-sectional diagram of an electrostatic capacitive sensor according to an example according to the present invention. As illustrated in FIG. 12, the diaphragm 11 has a mesa shape 111 on the bottom face thereof Note that the mesa shape 111 is not limited to a case wherein it is on the bottom face of the diaphragm 11. The mesa shape should be on the face that faces the space into which is filled the gas that has the higher coefficient of thermal expansion of the gas A1 and the gas A2. In the present form of embodiment, the gas A1 is a gas in a vacuum state, and the gas A2 is an inert gas, and thus the mesa shape would be on the face that faces the space S2 into which the gas A2 is filled, that is, on the bottom face of the diaphragm 11. Moreover, there may also be a mesa shape on the other face of the diaphragm 11, which, in the present example, is the top face.

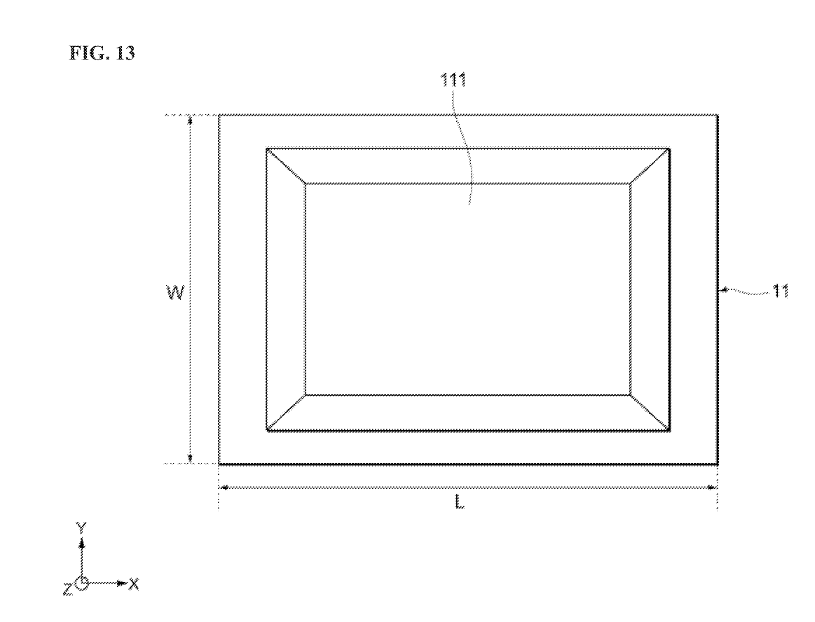

FIG. 13 is a plan view diagram for explaining the state of the diaphragm illustrated in FIG. 12. As illustrated in FIG. 13, the mesa shape 111 is formed in the center portion of the diaphragm 11 (the region in the center and the vicinity thereof). Note that the width (the length in the direction of the X axis in FIG. 13), length (the length in the direction of the Y axis in FIG. 13), and height (the length in the direction of the Z axis in FIG. 13) of the mesa shape may be varied as appropriate.

Here, in the same manner as in the above examples, when there is a pressure difference produced between the pressure in the space S1 and the pressure in the space S2, the diaphragm 11, which includes the mesa shape 111, tends to move with the face thereof remaining parallel, because it is difficult for the center portion of the face to deform into a curved shape (a concave shape). This makes it possible to detect the electrostatic capacitance C₁ and the electrostatic capacitance C₂ with excellent accuracy.

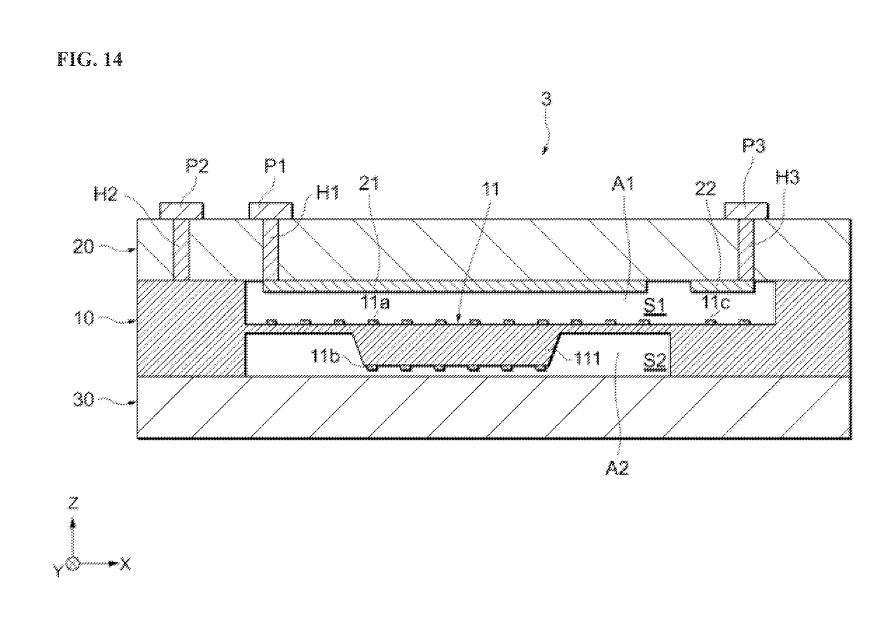

FIG. 14 is a side-view cross-sectional diagram illustrating another example of an electrostatic capacitive sensor according to another example. As illustrated in FIG. 14, even in the case wherein the electrostatic capacitive sensor 3 is provided with a reference electrode 22 in the same manner as in the above examples, still the diaphragm 11 includes a mesa shape 111 on the face that faces the space wherein is filled the gas having the higher coefficient of thermal expansion of the gas Al and the gas A2. In this case as well, the electrostatic capacitance C1 can be detected with excellent accuracy in the same manner as in the case illustrated in FIG. 12 and FIG. 13.

In this way, in the electrostatic capacitive sensor 3 in the present example, the diaphragm 11 has a mesa shape 111 on the face that faces the space wherein is filled the gas with the higher coefficient of thermal expansion of the gas A1 and the gas A2. Here, in the same manner as in the above examples, when there is a pressure difference produced between the pressure in the space S1 and the pressure in the space S2, the diaphragm 11, which includes the mesa shape 111, tends to move with the face thereof remaining parallel, because it is difficult for the center portion of the face to deform into a curved shape (a concave shape). This makes it possible to detect the electrostatic capacitance C₁ with excellent accuracy. This makes it possible to measure with even greater accuracy the temperature of that which is to be measured.

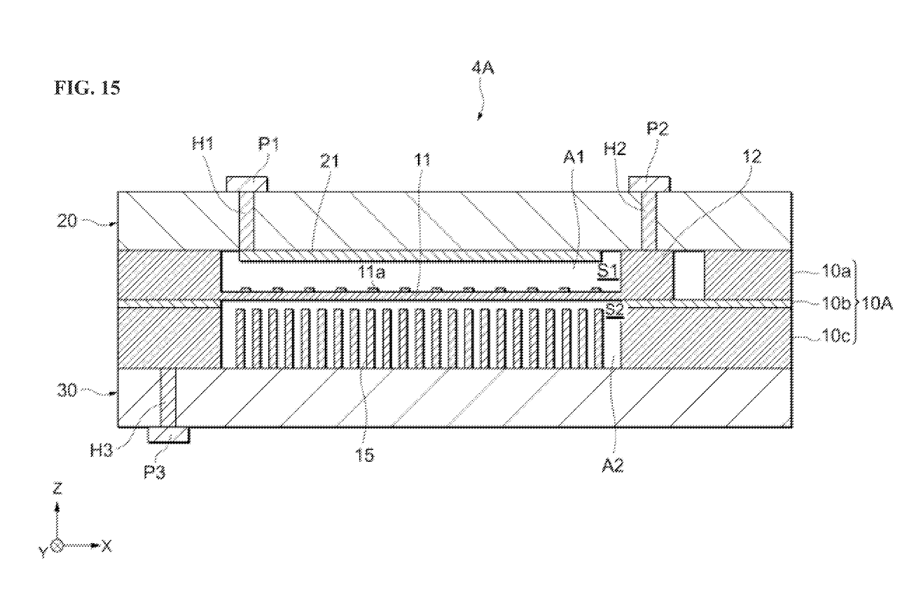

FIG. 15 through FIG. 17 are for explaining an example of an electrostatic capacitive sensor according to the present invention. Note that unless stated otherwise, identical structural parts as those in the above examples are indicated by identical codes, and explanations thereof will be omitted. Moreover, the structural elements not shown are identical to those in the examples set forth above.

The point of difference between this example and the others is that the electrostatic capacitive sensors 4A and 4B use an SOI (silicon on insulator) substrate 10A for the member 10.

FIG. 15 is a side-view cross-sectional diagram of an electrostatic capacitive sensor according to this example. As illustrated in FIG. 15, the SOI substrate 10A includes a silicon layer 10a, and insulating layer 10b, and a base silicon layer 10c.

The silicon layer 10a is structured from, for example, electrically conductive silicon. A diaphragm 11 and an electrically conductive portion 12 are formed in the silicon layer 10a. Here the use of the SOI substrate 10A that includes a silicon layer 10a designed at a specific thickness (the length in the direction of the Z axis in FIG. 15) enables the control of the thickness to be performed easily when, for example, performing etching.

The insulating layer 10b is structured from, for example, silicon oxide (SiO₂). Moreover, the insulating layer 10b is interposed between the silicon layer 10a and the base silicon layer 10c. The insulating layer 10b functions as an insulating layer for electrically insulating between the silicon layer 10a and the base silicon layer 10c.

The base silicon layer 10c is structured from, for example, electrically conductive silicon. An electrode portion 15 is formed in the base silicon layer 10c in a position facing the diaphragm 11. The electrode portion 15, forms an electrostatic capacitance C₂ with the diaphragm 11, in the same manner as with the thin-film electrode 31 in the first form of embodiment. The electrode portion 15 and the diaphragm 11 function as a capacitor.

Moreover, the electrode portion 15 is connected to a portion (not shown) that structures one portions of the base silicon layer 10c. This portion is connected electrically to an electrode pad (terminal) P3 that is disposed on the bottom face of the lower member 30 through a field through-hole electrode 142. The formation of the field through-hole electrode H2 is performed through forming the individual through-holes (not shown) in the lower member 30, and then performing filling film deposition, plating, filling wiring, or the like, for the electrode material into the through-holes, in the same manner as in the above examples.

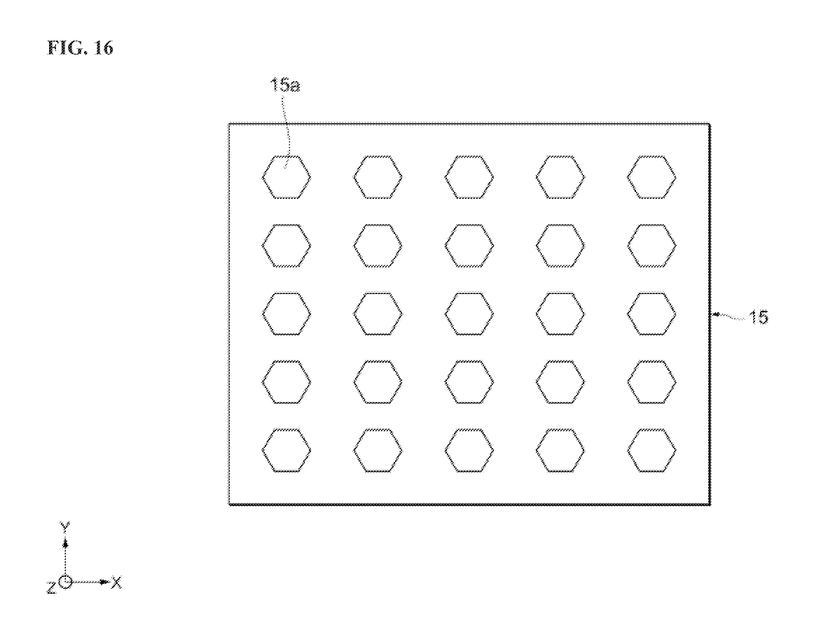

FIG. 16 is a top view diagram of the electrode portion illustrated in FIG. 15. As illustrated in FIG. 16, the electrode portion 15 has a plurality of columnar holes 15a that are lined up in the crosswise direction (the direction of the X axis in FIG. 16) and the lengthwise direction (the direction of the Y axis in FIG. 16) when viewed from above. These holes 15a are used when removing the insulating layer 10b. Typically, when removing an insulating layer 10b, a hydrofluoric acid vapor or buffered hydrofluoric acid (BHF) is used when removing an insulating layer 10b. However, even though these substances spread quickly in the vertical direction (the direction of the Z axis in FIG. 15 and FIG. 16), they have the property of having difficulties in spreading in the horizontal direction (the direction of the X axis and the direction of the Y axis in the 15 in FIG. 16). Consequently, it is possible to spread the hydrofluoric acid vapor or the buffered hydrofluoric acid (BHF) in the horizontal direction as well through having it flow in through these holes 15a.

Note that the shapes of the opening portions of the holes 15a are not limited to being equilateral hexagons, but rather may be circular shapes, elliptical shapes, rectangular shapes, square shapes, polygonal shapes, or the like. Note that a so-called honeycomb structure, having openings that are equilateral polygons, is structurally stable. Moreover, the number and size of holes 15a can be set as appropriate in consideration of the surface area on the top face of the electrode portion 15 that faces the diaphragm 11, and of the rate of removal of the insulating layer 10b.

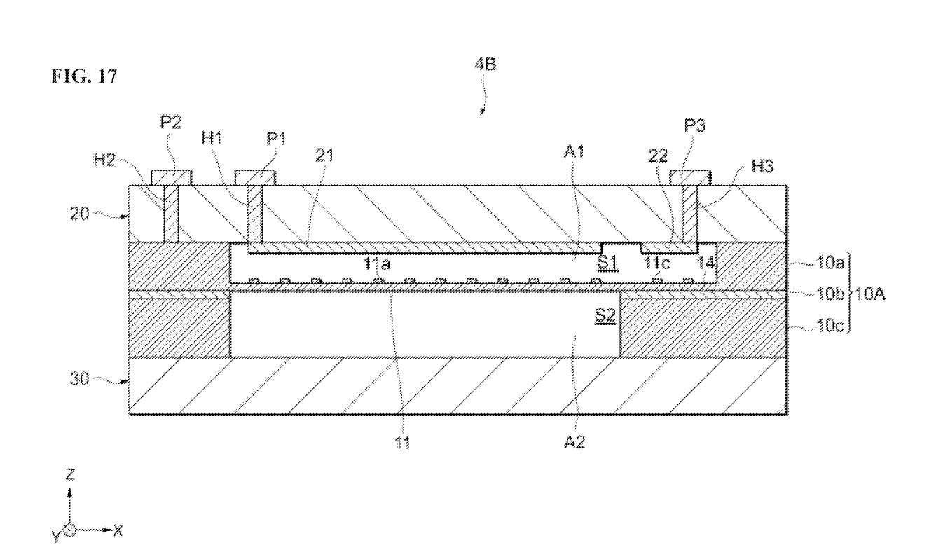

FIG. 17 is a side-view cross-sectional diagram illustrating another example of an electrostatic capacitive sensor. As illustrated in FIG. 17, an SOI substrate 10A is used as the member 10 even when the electrostatic capacitive sensor 4B is provided with a reference electrode 22 in the same manner as in the above examples. In this case as well, as with the case illustrated in FIG. 15, the use of the SOI substrate 10A that includes a silicon layer 10a designed at a specific thickness (the length in the direction of the Z axis in FIG. 17) enables the control of the thickness to be performed easily when, for example, performing etching.

In this way, in the electrostatic capacitive sensors 4A and 4B in the present example, the SOI substrate 10A includes a silicon layer 10a wherein a diaphragm 11 is formed, a base silicon layer 10c, and an insulating layer 10b that is interposed between the silicon layer 10a and the base silicon layer 10c. Here the use of the SOI substrate 10A that includes a silicon layer 10a designed at a specific thickness (the length in the direction of the Z axis in FIG. 15 and FIG. 17) enables the control of the thickness to be performed easily when, for example, performing etching. This makes it possible to form the diaphragm 11 easily.

Moreover, in the electrostatic capacitive sensor 4A in the present example, the SOI substrate 10A includes a silicon layer 10a wherein a diaphragm 11 is formed, a base silicon layer 10c wherein an electrode portion 15 is formed, and an insulating layer 10b that is interposed between the silicon layer 10a and the base silicon layer 10c. Here, when removing an insulating layer 10b, a hydrofluoric acid vapor or buffered hydrofluoric acid (BHF) is used when removing an insulating layer 10b. However, even though these substances spread quickly in the vertical direction (the direction of the Z axis in FIG. 12 and FIG. 13), they have the property of having difficulties in spreading in the horizontal direction (the direction of the X axis and the direction of the Y axis in the 15 in FIG. 16). Consequently, it is possible to spread the hydrofluoric acid vapor or the buffered hydrofluoric acid (BHF) in the horizontal direction as well through having it flow in through these holes 15a. Doing so makes it possible to remove cleanly (completely) the insulating layer 10b in the part corresponding to the diaphragm 11.

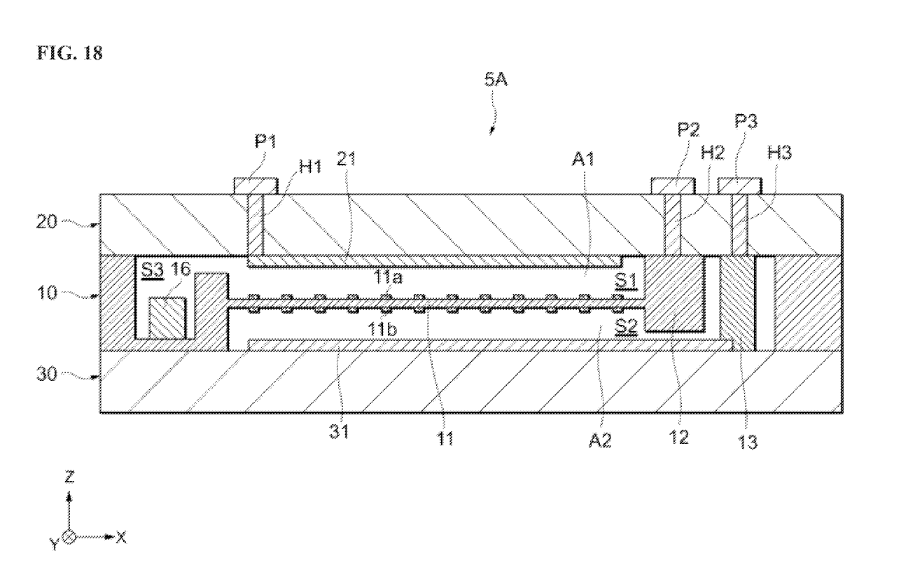

FIG. 18 through FIG. 21 are for explaining a yet another example of an electrostatic capacitive sensor according to the present invention. Note that unless stated otherwise, identical structural parts as those in the above examples are indicated by identical codes, and explanations thereof will be omitted. Moreover, the structural elements not shown are identical to those in the examples set forth above.

The point of difference between the examples is that a gettering chamber S3 is formed in the member 10 in the electrostatic capacitive sensors 5A and 5B and in the SOI substrate 10A in the electrostatic capacitive sensors 5C and 5B.

FIG. 18 is a side-view cross-sectional diagram of an electrostatic capacitive sensor according to a fifth form of embodiment according to the present invention. As illustrated in FIG. 18, a gettering chamber S3 is formed communicating with the space S1 in the member 10. Gettering material 16 is contained in the gettering chamber S3. The gettering material has the nature of adsorbing (absorbing) gases, and, for example, may use a non-volatile gas adsorbing layer or a commercially available gas absorbing material. Note that a gettering material may be used to deposit a thin-film electrode 21 on the bottom face of the upper member 20.

As described above, the gas Al that is filled into the space S1 is a gas in a vacuum state. As a result, the gettering material 16 that is contained in the gettering chamber S3 adsorbs the gas that is residual in the space S1, making it possible to increase the level of the vacuum for the gas A1 that is filled in the space S1.

In particular, when bonding the member 10 and the upper member 20 through the anode bonding method, oxygen (or oxygen ions) may be released from the upper member 20 that is structured from glass, or the like. In this case, this may prevent a reduction in the vacuum level of the gas A1.

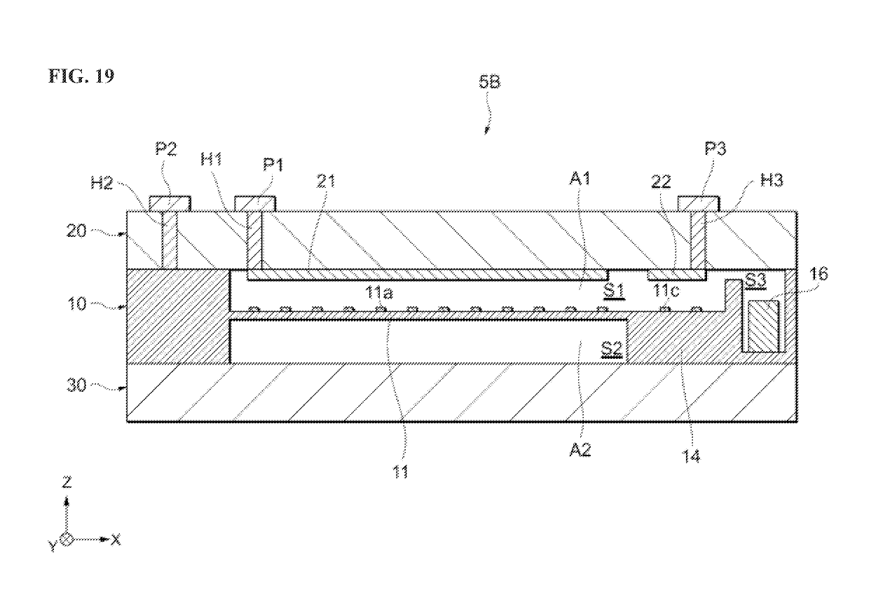

FIG. 19 is a side-view cross-sectional diagram illustrating another example of an electrostatic capacitive sensor. As illustrated in FIG. 19, the gettering chamber S3 is formed in the member 10 even in the case wherein the electrostatic capacitive sensor 5B is provided with a reference electrode 22 in the same manner as in the above examples. In this case as well, the gettering material 16 that is contained in the gettering chamber S3 absorbs the gas that is residual in the space S1 in the same manner as in the case illustrated in FIG. 18, making it possible to increase the level of the vacuum for the gas A1 that is filled into the space S1.

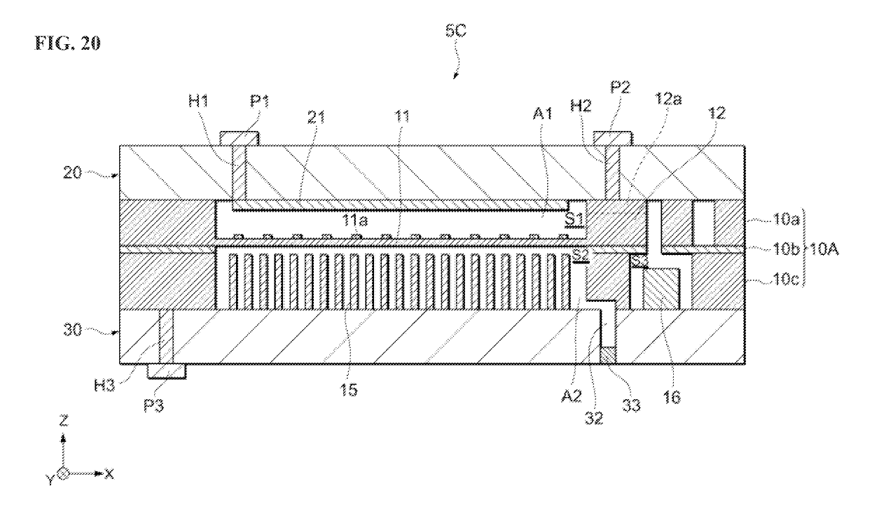

FIG. 20 is a side-view cross-sectional diagram illustrating another example of an electrostatic capacitive sensor. As illustrated in FIG. 20, a gettering chamber S3 is formed in the SOI substrate 10A, and, specifically, in the base silicon layer 10c, even in the case wherein the electrode portion 15 is formed when the electrostatic capacitive sensor 5C uses an SOI substrate 10A as the member 10 in the same manner as in FIG. 15 which was shown in the above example. Note that this is just because it is easier to form the gettering chamber S3 in the base silicon layer 10c, which is thicker than the silicon layer 10a, but it can be formed instead in the silicon layer 10a.

A connecting hole 12a is formed in the electrically conductive portion 12 so as to connect the space S1 and the gettering chamber S3. Moreover, a through-hole 32 is formed in the lower member 30 so as to fill the gas A2 into the space S2. The opening portion of the through-hole 32 is sealed by a sealing material 33 after the SOI substrate 10A is bonded to the lower member 30 and the gas A2 is introduced into the space S2.

Note that when bonding the SOI substrate 10A to the lower member 30, the space S2 is filled with atmosphere (air). The unit can be moved in this state to a location wherein the pressure is low, to draw the atmosphere (air) out of the space S2, to replace it with the gas A2.

In this case as well, the gettering material 16 that is contained in the gettering chamber S3 absorbs the gas that is residual in the space S1 in the same manner as in the case illustrated in FIG. 18, making it possible to increase the level of the vacuum for the gas A1 that is filled into the space S1.

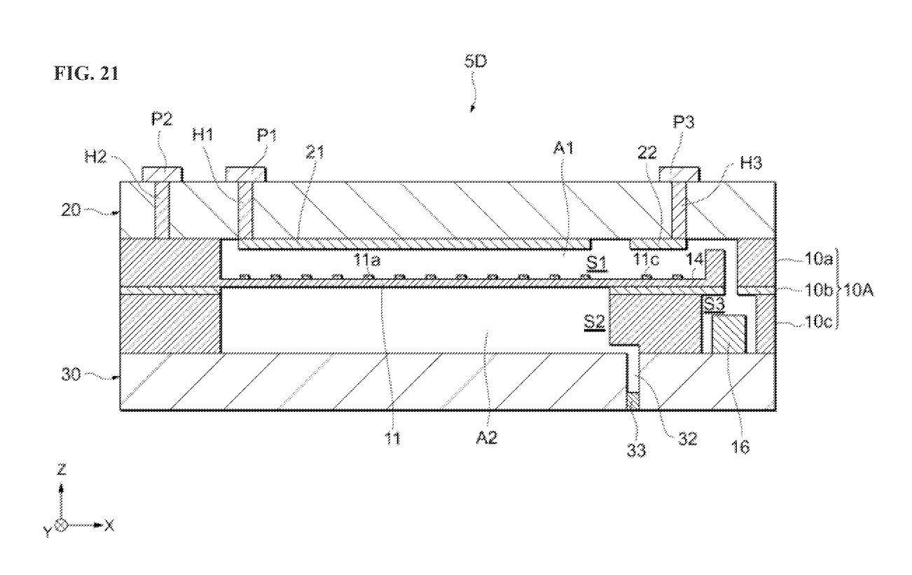

FIG. 21 is a side-view cross-sectional diagram illustrating another example of an electrostatic capacitive sensor according to the present invention. As illustrated in FIG. 21, a gettering chamber S3 is formed in the SOI substrate 10A, and, specifically, in the base silicon layer 10c, even in the case wherein reference electrode 22 is provided when the electrostatic capacitive sensor 5D uses an SOI substrate 10A as the member 10 in the same manner as in FIG. 22 which was shown above. Note that the gettering chamber S3 may instead be formed in the silicon layer 10a, in the same manner as in the case illustrated in FIG. 20.

A through-hole 32 is formed in the lower member 30 so as to fill the gas A2 into the space S2. The opening portion of the through-hole 32 is sealed by a sealing material 33 after the SOI substrate 10A is bonded to the lower member 30 and the gas A2 is introduced into the space S2. In this case as well, the gettering material 16 that is contained in the gettering chamber S3 absorbs the gas that is residual in the space S1 in the same manner as in the case illustrated in FIG. 18, making it possible to increase the level of the vacuum for the gas A1 that is filled into the space S1.

In this way, in the electrostatic capacitive sensors 5A, 5B, 5C, and 5D according to the present examples, a gettering chamber S3 that contains a gettering material 16 is formed in communication with the space S1 in the member 10 or the SOI substrate 10A, and the gas A1 that is sealed in the space S1 is in a vacuum state. As a result, the gettering material 16 that is contained in the gettering chamber S3 adsorbs the gas that is residual in the space S1, making it possible to increase the level of the vacuum for the gas A1 that is filled in the space S1.

Note that the structures in the various forms of examples set forth above may be combined, or portions of the structural parts thereof may be substituted. Moreover, the structure in the present invention is not limited to only the forms of example set forth above, but rather a variety of modifications may be applied thereto within a scope that does not deviate from the spirit or intent of the present invention.

The present invention can be applied to technologies that perform intermittent operations to measure temperatures.

1. An electrostatic capacitive sensor able to detect a first electrostatic capacitance and a second electrostatic capacitance, comprising:
a first member wherein is formed a movable electrode plate that has electrical conductivity;
a first electrode forming a first electrostatic capacitance with the electrode plate;
a second electrode forming a second electrostatic capacitance with the electrode plate;
a second member forming a first space between itself and one face of the electrode plate; and
a third member forming a second space between itself and the other face of the electrode plate; wherein:
a first gas is filled into the first space and a second gas, which has a coefficient of thermal expansion different from that of the first gas, is filled into the second space.

2. An electrostatic capacitive sensor able to detect a first electrostatic capacitance and a second electrostatic capacitance, comprising:
a first member wherein is formed a movable electrode plate that has electrical conductivity;
a first electrode forming a first electrostatic capacitance with the electrode plate;
a second electrode forming a second electrostatic capacitance;
a second member forming a first space between itself and one face of the electrode plate; and
a third member forming a second space between itself and the other face of the electrode plate; wherein:
a first gas is filled into the first space and a second gas, which has a coefficient of thermal expansion different from that of the first gas, is filled into the second space.

3. The electrostatic capacitive sensor as set forth in claim 2, wherein:
the first member has electrical conductivity, and forms an electrode portion that forms a second electrostatic capacitance with the second electrode.

4. The electrostatic capacitive sensor as set forth in claim 2, further comprising:
a third electrode forming a second electrostatic capacitance with the second electrode.

5. The electrostatic capacitive sensor as set forth in claim 2, further comprising:
a fourth member, having electrical conductivity, wherein is formed an electrode portion forming the second electrostatic capacitance with the second electrode.

6. The electrostatic capacitive sensor as set forth in claim 1, wherein:
the electrode plate has a mesa shape on the face that faces the space into which is filled the gas, of the first gas and the second gas, that has the higher coefficient of thermal expansion.

7. The electrostatic capacitive sensor as set forth in claim 1, wherein:
the first member includes a first electrically conductive layer wherein the electrode plate is formed, a second electrically conductive layer, and an insulating layer that is interposed between the first electrically conductive layer and the second electrically conductive layer.

8. The electrostatic capacitive sensor as set forth in claim 1, further comprising:
the first member includes a first electrically conductive layer wherein the electrode plate is formed, a second electrically conductive layer wherein the second electrode is formed, and an insulating layer that is interposed between the first electrically conductive layer and the second electrically conductive layer.

9. The electrostatic capacitive sensor as set forth in claim 1, wherein:
the first member is formed with a third space that contains a gettering material and that is connected to the first space; and
the first gas is at a vacuum state.
